(19) United States
(12) Patent Application Publication
(10) Pub. No.: US 2006/0272701 A1
(43) Pub. Date: Dec. 7, 2006

(54) Nanotube-organic photoelectric conversion device and methods of making same

(76) Inventors: Pulickel Ajayan, Troy, NY (US); Amanda Ellis, Troy, NY (US); Chang Y. Ryu, Troy, NY (US); Seamus Curran, Troy, NY (US)

Correspondence Address: FOLEY AND LARDNER LLP;SUITE 500, 3000 K STREET NW, WASHINGTON, DC, 20007, US

(21) Appl. No.: 10/537,943

(22) PCT Filed: Dec. 9, 2003
(86) PCT No.: PCT/US03/38952

§ 371 Date: Jun. 26, 2006

Related U.S. Application Data
(60) Provisional application No. 60/431,948, filed on Dec. 9, 2002.

(51) Int. Cl. H01L 31/00

(52) U.S. Cl. 136/263

(57) ABSTRACT

An organic photovoltaic conversion device, such as a solar cell includes a matrix material, such as a polymer matrix material, carbon nanotubes dispersed in the matrix material, and photovoltaic organic molecules, such as organic dye molecules, attached to defect sites on the carbon nanotubes.

### CROSS-REFERENCE TO RELATED APPLICATIONS

This application claims priority to U.S. Provisional Application Ser. No. 60/431,948, filed Dec. 9, 2002, the disclosure of which is incorporated by reference herein in its entirety.

### FIELD OF THE INVENTION

The present invention is directed to nanotube-organic photoelectric conversion devices, such as solar cells, and methods of making thereof.

### BACKGROUND OF THE INVENTION

Carbon nanotubes (CNTs) are self-assembled coaxial cylindrical graphene sheets of sp² hybridized carbon atoms. There are two types of CNTs, multi-walled carbon nanotubes (MWNT) and single-walled carbon nanotubes (SWNT).

In recent years, much interest has focused on energy consumption where alternative sources of power have been examined. Currently, most solar panels are made from silicon (monocrystalline, polycrystalline and amorphous states) in large flat panels. While reasonable efficiencies have been achieved (10-20%), they are still limited in general use due to the prohibitive costs. Much work has been done in the area of obtaining more suitable materials and GaAs format solar panels (with different doping levels and species) and efficiencies of 30-40% may be now obtained. However, the inhibiting factor is still costs and applicability. What is meant by applicability is that most panels are large and unwieldy, considering the amount of power generated. It is difficult to produce panels that can be applied to any surface, such as curved, ceramic, metallic or plastic. Hence this morphology problem exacerbates the problem.

Extensive research has been carried out on organic and polymer systems over the last decade to determine optimum optical and electrical properties for possible electronic and opto-electronic applications. Progress towards producing polymeric materials in a robust opto-electronic fashion creates a host of problems which include sensitivity to intensity (power) within the polymer, long term instabilities due to photo-chemical effects, low thermal and electrical conductivity (necessary for transport related functions), and relatively low third order effects. Novel approaches to property tailoring in polymer systems are desired to maximize the beneficial properties of the polymers while reducing their inherent deficiencies.

### SUMMARY OF THE INVENTION

One aspect of the present invention provides an organic photovoltaic conversion device comprising a matrix material, carbon nanotubes dispersed in the matrix material, and photovoltaic organic molecules attached to defect sites on the carbon nanotubes.

### BRIEF DESCRIPTION OF THE DRAWINGS

FIG. 1 shows a charge-transfer complex formation between carboxylated multi-walled carbon nanotubes (MWNTs) and Phenosafranin (PSF).

FIG. 2 shows the UV-visible spectra of pristine MWNTs, acid treated MWNTs, and acid treated MWNTs after PSF dye attachment.

FIGS. 3A and 3B show normalized Raman spectra at different stages of nanotube functionalization.

FIGS. 4A and 4B are AFM images of a single multi-walled nanotube with dye attachments on defect sites.

FIGS. 5A and 5B are schematic illustrations of carbanion formation and subsequent initiation of charge transfer complex formation.

FIGS. 6 and 7 are SEM images of nanotubes embedded in a polymer matrix.

FIG. 8 is an SEM image of nanotubes aligned along the polymer fiber stretching direction.

### DETAILED DESCRIPTION OF THE PREFERRED EMBODIMENTS

The following describes certain preferred embodiments of the invention. It should be understood that this description is intended merely to be exemplary of the invention.

An organic photovoltaic conversion device includes a matrix material, carbon nanotubes dispersed in the matrix material, and photovoltaic organic molecules attached to defect sites on the carbon nanotubes. Any suitable carbon nanotubes may be used, such as multi-walled and single walled nanotubes. The multi-walled nanotubes are preferred. The photovoltaic organic molecules are adapted to generate a photocurrent upon absorbing radiation. Preferably, these molecules comprise organic dyes which are chemisorbed to the defect sites on the carbon nanotubes such that the absorbed radiation provides excitation transfer from the photovoltaic organic molecules to the carbon nanotubes. Any suitable matrix material may be used. Preferably, the matrix material comprises a polymer material.

The carbon nanotubes with attached photovoltaic molecular species on the body of the tubes form so called SuperNanoMolecular (SNM) structures. The molecular species attached to the nanotubes is selected for its optical properties. The photovoltaic (i.e., absorptive) molecules attach onto the nanotubes that possess strong photoconductive properties. These properties enhance the SuperNanoMolecular (SNM) structures ability to act as the active electronic component for photovoltaic device. The photovoltaic conversion device is preferably a solar cell, but may also be used as a photodetector if desired.

The SNM structures are then mixed with or otherwise incorporated into a polymer matrix by any suitable method. A polymer is preferably, but not necessarily, produced from interfacial polymerization that is used to align the SuperNanoMolecular (SNM) structures to ensure more efficient carrier conduction in a specific direction. In other words, the interfacial polymerization may be used to align the nanotubes so that the nanotubes can carry current in a controlled direction, making the devices more efficient.

One means of addressing some of the deficiencies of polymers in an electronic manner is the dispersion of nanostructures to create a polymer matrix that derives its electronic behavior from cooperative behavior between the host and additive. Nanotubes have only recently been used as electrical or mechanical inclusions in a polymer matrix because of the difficulty in achieving efficient dispersion. This difficulty is primarily due to the non-reactive surface of pristine nanotubes. The present inventors believe that the first solubility for nanotubes in a polymer matrix was reported only several years ago where the polymer used (PmPV) also acted as a filter for nanoparticles, resulting in a more purified sample of polymer and nanotubes in a composite. However, intrinsic van der Waals attractions among tubes, in combination with their high surface area and high aspect ratio, often leads to significant agglomeration, thus preventing efficient transfer of their superior properties to the matrix.

The methods of the embodiments of the present invention provide methods of reducing the nanotube aggregation effect and dispersing the nanotubes in a more ordered fashion to enhance the overall macro properties of the host polymer. The methods of the embodiments of the present invention also provide flexible, durable and enhanced performance of organic solar cells and other photovoltaic devices

The preferred embodiments of the methods of making the photovoltaic devices will now be described. The carbon nanotubes can be formed by any suitable method, such as HiPCO, arc discharge or CVD. If desired, the nanotubes may be purified through a variety of methods, including oxidative methodologies, such as ozone treatment, attachments with sulphonic acids, ultrasonification or simple plasma treatment. The resultant nanotubes are substantially free of amorphous materials and polyhedra. Most carbon nanotubes end up with ‘functionalized’ defect sites on the nanotube body. These sites can be in the form of structural defects (in the case of pentagon and heptagon formation or preferably by formation of bonding groups as will be described in more detailed below), or they can simply be sp³ formation and possessing dangling bonds. These susceptible or reactive defect sites serve as positions to bring other photovoltaic molecules along and attach them to the nanotubes. These molecules can be in the form of large complex polymers (from conjugated to non-conjugated systems) or small molecules, even in the case of atoms such as Se, simply colloidal type structures. The molecules that have strong photo-absorptive tendencies are attached onto the nanotubes, and this enhanced molecular structure can be used to tune the SNM structures for optical properties in order to enhance the optical photoconductive effect. The polymer matrix can be used as a protective and holding matrix as well as for alignment of the nanotubes themselves. The use of interfacial polymerization allows fibers and thin films to be produced over any surface.

In a method of the first preferred embodiment, organic dye molecules are attached to defect sites induced on nanotubes, such as multi-walled carbon nanotube (MWNT) sites by an acid treatment. The acid treatment forms carboxyl groups on the nanotube defect sites. The carboxyl groups are used to covalently bind or chemisorb the dye molecules to the nanotubes.

In a preferred aspect of the first embodiment, a cationic phenazine dye, phenosafranin (PSF), is used. However, any other suitable dye may be attached to the nanotubes in a similar fashion. PSF is advantageous because phenazine dyes have great potential for use in solar cells. For example, PSF coupled with EDTA generates photovoltages of about 600 mV. In addition, PSF can undergo reversible reduction with long-lived excited states which make it a good photosensitizer in energy and electron transfer reactions. The amine functionalities make PSF suitable for dispersion in Nylon 6 or other similar polymer matrices, since the amine functionalities may be incorporated into Nylon 6 polymer backbone.

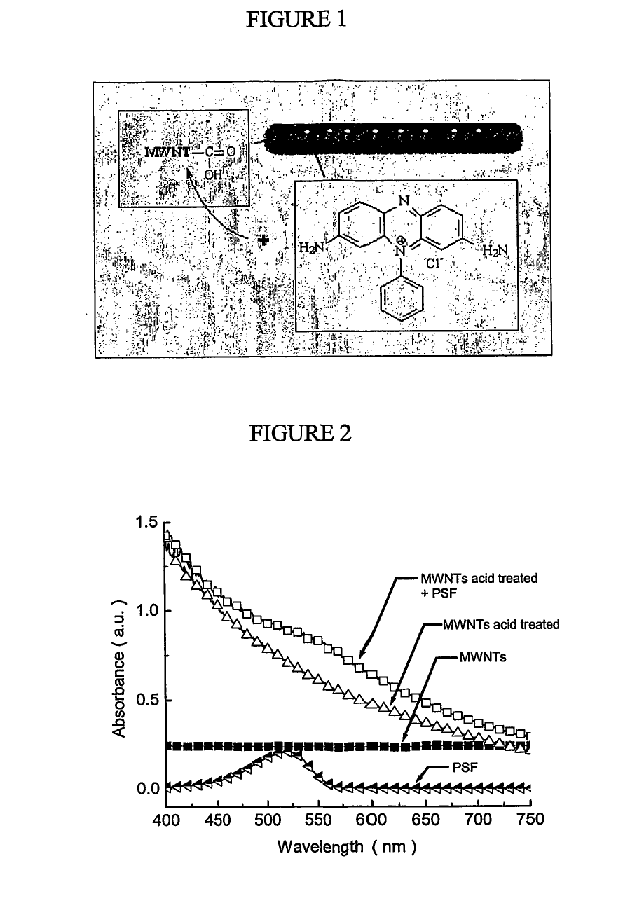

The following specific but non-limiting example of the method of the first embodiment is presented for illustration of the method. MWNTs synthesized by the arc-discharge method were first purified by sonication in concentrated 70/30 H₂SO₄/HNO₃ in an ultrasonic bath for 6 hours. Other acids and purification methods may also be used. The nanotubes were then filtered through a Whatman nylon microfilter, 0.20 μm, and washed with deionized water. This method of chemical functionalization creates dangling bonds that are progressively oxidized depending upon the intensity of treatment to hydroxyl (—OH), carbonyl (>C═O) and carboxyl groups (—COOH). Synthesis of phenosafranin (3,7-diamino-5-phenylphenazine or PSF) functionalized MWNTs was achieved by mixing 3 mg of carboxylated nanotubes in 5 mL of deionized water containing 0.1% v/v PSF, as schematically illustrated in FIG. 1. After mixing, the solution was sonicated for 1 minute. While the carboxylated tubes appeared soluble in deionized water, after the addition of the PSF there is a notable change in their solubility as the nanotubes segregate from the solution, a clear indication of PSF attachment. The product was filtered under vacuum through a 0.2 μm nylon microfilter and washed thoroughly with deionized water, then air-dried and stored in a desiccator.

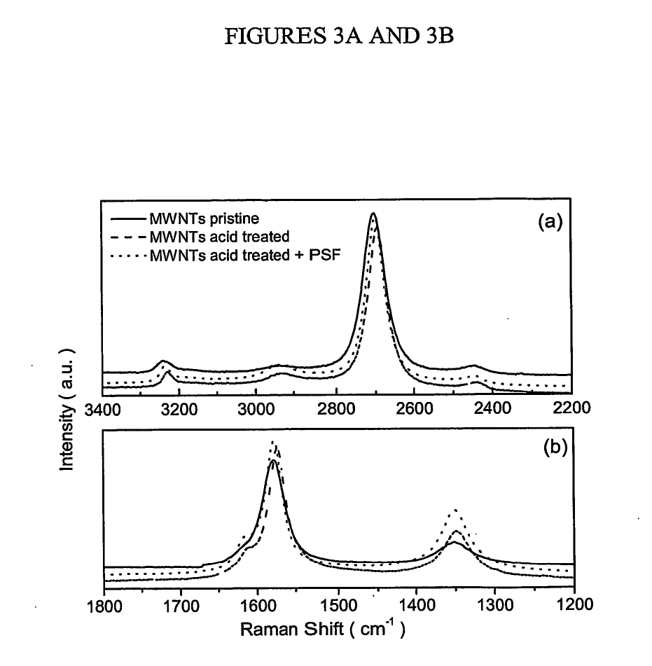

FIG. 2 illustrates UV-Visible absorption spectra (plots of absorbance versus wavelength) of PSF, pristine MWNTs, acid treated MWNTs and acid treated MWNTs after PSF dye attachment. Notably, Mie scattering is observed after acid treatment of the tubes (compared to the pristine tubes), characterized by the rapid increase in base line at decreasing wavelengths. Without wishing to be bound by a particular theory, the present inventors believe that this phenomenon is caused by the acid treatment creating shortened tubes of similar length scales and electrical characteristics such that they can separate or disperse different wavelengths of light.

The absorption maximum for PSF is at 520 nm (2.38 e.V) while the absorption maximium for the broad band of PSF treated carboxylated nanotubes is 562 nm (2.21 e.V), a shift of 0.17 e.V (FIG. 2). Without wishing to be bound by a particular theory, the present inventors believe that this bathochromic or red-shift indicates chemisorption, primarily due to the phenosafranin/MWNT interaction which allows excitation transfer (caused by light) from the phenosafranin dye to the nanotube, and visa versa. This would indicate that the bond formation or charge transfer process is far stronger than a simple electrostatic process. Carbon nanotubes, in general, are believed to be good electron acceptors. In this case, it is believed that the dye has attached to the nanotube. The result is that there is a drop in the dye molecules Homo-Lumo gap due to the electron transfer process. Consequently, a decrease in vibrational freedom inflicted by the new charge transfer process takes place as valence electrons are transferred from the PSF attached molecule into the carbon π* band.

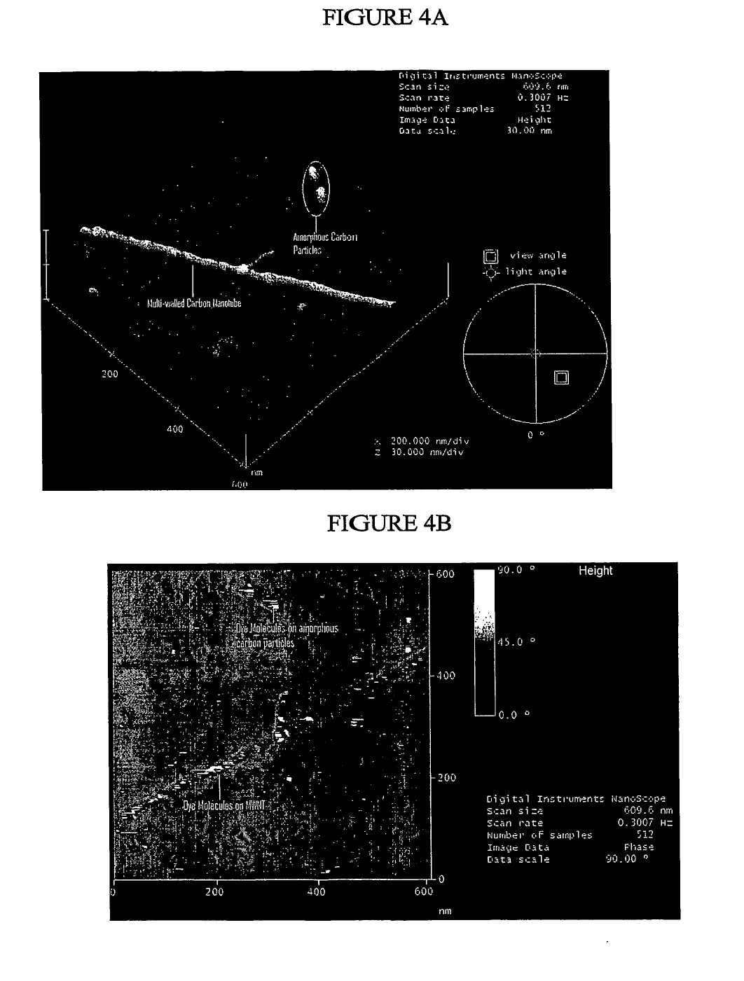

FIG. 3 shows normalized Raman spectra at different stages of the nanotube functionalization (pristine nanotubes, acid treated nanotubes (i.e., carboxylated), and PSF and acid treated nanotubes). The functionalized MWNTs are characterized by Raman spectroscopy using a Ar⁺ laser operating at 514.7 nm. The spectra shows two main characteristic first order peaks for the MWNTs. The Raman peak of the E_{2g} optical phonon is observed at 1580 cm⁻¹ and is believed to be due to in-plane vibration of a graphite layer (G mode) (FIG. 3B). The peak at 1350 cm⁻¹ is believed to be a disorder induced D mode resulting from impurities and lattice distortions in CNT's. Without wishing to be bound by a particular theory, the present inventors believe that as the perfect 2-D graphitization of the MWNTs is altered to a more disordered structure upon acid treatment, a strain is introduced in the C═C bond vibrations which gives rise to an increase in the intensity of the D peak. In addition the D peak narrows as more amorphous carbon and polyhedra are removed from the sample. Due to the acid treatment, the E_{2g} peak splitting is observed, with the G peak downshifted by 5 cm⁻¹, from 1581 cm⁻¹, and a new peak appearing at 1617 cm⁻¹, denoted D′ resolving (FIG. 3B). Without wishing to be bound by a particular theory, the present inventors believe that this peak can be associated with defects arising from the nanotube body, as observed through plasma treatment elsewhere. Without wishing to be bound by a particular theory, the present inventors believe that the step of adding PSF removes many of the acid activated sites on the graphene outer layer of the MWNT's, as the MWNT outer layer attracts the PSF to the surface, and through self-assembly PSF-CNT functionalization occurs. Consequently, the D′ peak is reduced in intensity as the PSF sits on the acid treated reactive sites of the nanotubes.

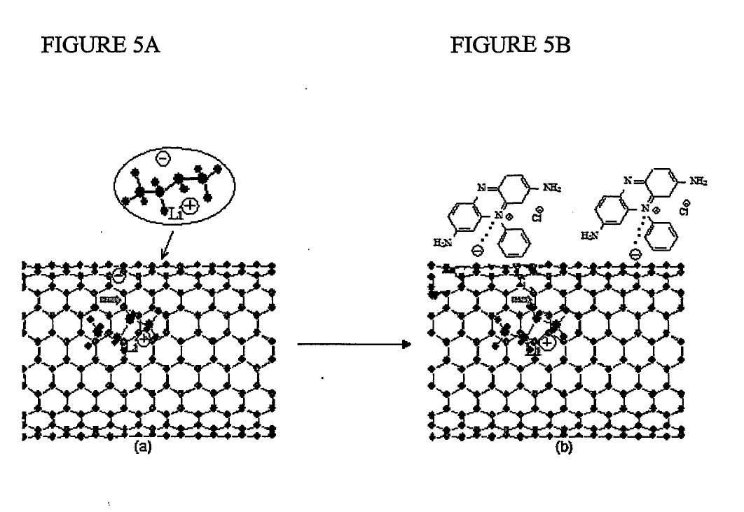

FIGS. 4A and 4B are AFM images of PSF dye and acid treated nanotubes. FIG. 4A is a height image (deflection) showing no apparent change in height on the locations of dye molecules. FIG. 4B is a phase image showing clear contrast on regions of dye attachments at defect sites on the MWNT. A Digital Instrument Multimode Scanning Probe Microscope with a Nanoscope IIIa controller was used to image the nanotubes and dye attached nanotubes. Phase imaging, in tapping mode, using an oscillating probe was used to obtain nanometric images. This goes beyond topographic details to measure changes in surface properties such as composition, adhesion, hardness, viscoelasticity, and more, by mapping the change in the phase of the cantilever oscillations. Samples for AFM measurements were prepared by drop-casting the solution of nanotubes dispersed in water onto a freshly cleaved highly oriented pyrolytic graphite (HOPG) substrate. This was then dried in air until the water has evaporated, leaving only nanotubes on the HOPG substrate. While no large change in topography could be observed at the sites of the dye attachment (FIG. 4A), attributed to the sub-nanometer size of the dye molecules, a more prominent contrast was detected in the phase-image (FIG. 4B) at locations where the dye molecules were attached to defect sites on the nanotubes. This is as would be expected if the dye molecules in self-assembly attach only at CNT defect sites. In the Phase image, minimal contrast is observed between the HOPG substrate and the multi-walled nanotubes owing to the similar graphitic nature of both materials. However, at locations where dye molecules are attached to the tube, the PSF material that is attached to the nanotube is visible. However, MWNT coverage is not complete as the PSF only adheres to acid activated defect sites, and consequently there is not aggregation of the dye on the entire length of the nanotube body.

The results in FIGS. 2, 3 and 4 show that phenosafranin (PSF) attaches to MWNT at acid treatment induced defects along the nanotube body. The attachment of the organic dye PSF was achieved through the process of self-assembly whereby the dye attaches on top of these induced defect sites. Spectroscopic verification using UV-Visible and Raman spectroscopy showed a bathochromic shift in the UV-Visible spectrum indicative of an electron transfer process between the nanotubes and PSF. In addition, the changes in the nanotube morphology were spectroscopically fingerprinted as being due to self-assembly, indicated by changes in the D, G and D′ vibrational position of the Raman spectra. Finally, using AFM, in tapping mode and Phase image control, the carbon nanotubes and the attached PSF were distinguished. It believed that the attachment was selective in that the only positions available for self-assembly attachment were at the defect sites. This allows organic molecules, such as optoactive dyes, to alter the morphology and more concisely tailor the optical properties of nanotubes to meet more specific needs, optically, electronically or biomedically.

A method of the second preferred embodiment will now be described. In this method, organic dye molecules are attached to defect sites induced on single-walled carbon nanotube (SWNT) sites by an anionic initiator (i.e., ionization agent) in an anionic treatment. The carbon nanotubes are reacted with an anionic initiatior thereby generating anions (i.e., defect sites) on the surface of the carbon nanotubes. The photovoltaic organic molecules are covalently bonded to the anions. Specifically, this method introduces carbanions onto the single or multiwall nanotube surface by treatment with an anionic initiator, such as sec-butyllithium. This method is believed to increase the charge transfer density of the photovoltaic device and serves to exfoliate, separate and negatively charge the nanotube bundles providing a high density of initiating sites for cationic phenazine dye attachment.

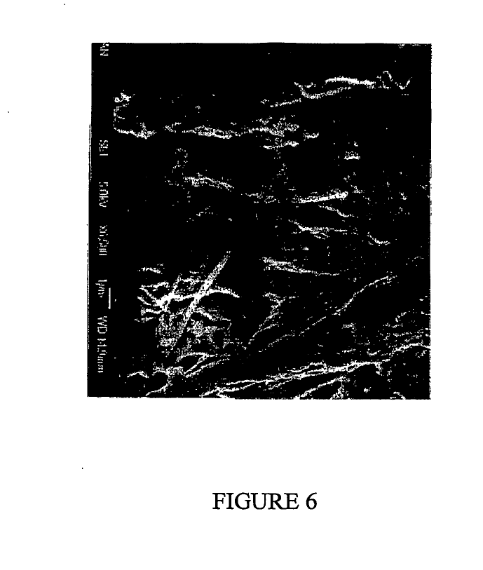

FIGS. 5A and 5B are schematic illustrations of carbanion formation and subsequent initiation charge transfer complex formation. FIG. 5A illustrates a section of SWNT sidewall showing sec-butyllithium addition to a double bond (large arrow indicates the bond to which it adds) and formation of anion via transfer of charge. FIG. 5B shows how the carbanion transfers the negative charge to cationic phenosafranin (i.e., PSF formed from a chloride salt).

The anionic process of the second embodiment of the invention involves the use of an ionizing agent or anionic initiator. An anionic initiator is any agent which can add to double bonds on the nanotube surface thereby generating anions (carbanions) on the surface of the nanotubes. Anionic initiators include, for example, metal organic initiators such as alkyl lithium compounds (salts), such as sec-butyllithium, as well as other alkali metal organic compounds, such as fluorenyl-sodium and cumyl-sodium. Radical ionic initiators such as sodium naphthalenide may also be used.

In one aspect of the second embodiment, anions that are formed on the surface of the nanotubes using the anionic process are subsequently quenched (i.e., protonated) with an alcohol (e.g., methanol or ethanol). The resulting nanotubes may be considered to be derivatized by virtue of the fact that the ionizing agent which has added to the nanotube double bond is still attached. When the anionic initiator used is an alkyl lithium salt, for example, the derivatized, well-dispersed nanotubes are alkyl-derivatized, well-dispersed nanotubes. For example, the defect sites may comprise C₁₋₆ alkyl groups. Thus, if sec-butyl lithium is used as the anionic initiator, the nanotubes will have sec-butyl groups attached to their surface. In short, the skilled artisan will appreciate that the nanotube surface will comprise the anionic initiator attached thereto at the defect sites, even when the resulting anion is subsequently reacted with the cationic dye.

In the context of derivatized, well-dispersed CNTs, “derivatized” and “well-dispersed” have the following meaning. “Well-dispersed” means that the nanotubes are substantially homogeneously distributed (i.e., allowing for a 1 to 20 percent, preferably 1 to 5 percent inhomogeniety in certain regions of the matrix) in the matrix without phase separation. Preferably, a majority of the well dispersed CNTs are not bundled together. Preferably, about 60%, more preferably about 80%, most preferably about 90% of the derivatized, well-dispersed CNTs are not bundled together. “Derivatized” means that the derivatized, well-dispersed CNTs contain bonding groups on their surface. An example of a bonding group in the context of the second embodiment of the present invention is a C₁₋₆ alkyl group.

The following specific but non-limiting example of the method of the second embodiment is presented for illustration of the method. HiPCO singe wall carbon nanotubes (SWNTs) were obtained from Carbon Nanotechnologies Inc. (Houston, USA). The tubes have an average length around 1 μm and the predominant impurities are iron catalyst particles (5-6 at. %). To ensure that the nanotubes are free of air and absorbed moisture prior to derivatization, they were dried under dynamic vacuum (10⁻³ torr) at 200° C. for 12 hours and subsequently stored under argon. SWNTs produced by the HiPCO process, were used without further purification, as purification procedures might introduce functionalities that hinder carbanion formation.

An alkyllithium, R(−)Li(+) (e.g. sec-butyllithium) in a slight excess amount sufficient to remove protic impurities on the SWNT surface is reacted with dried SWNTs dispersed by sonification in a solvent, such as purified cyclohexane, to induce the formation of carbanions in the carbon nanotubes and thereby grafting the alkyl groups onto the SWNT surface. During this process, the SWNTs are well-dispersed/debundled due to the electrostatic repulsion between negatively charged SWNTs during the reaction. Since bundling of SWNT no longer exists, the reaction solution remain homogenous. The SWNTs are suitable for attachment of the photovoltaic dye molecules, as illustrated in FIG. 5B and as described in the method of the first embodiment. Degassed protic alcohol, such as methanol and/or buthanol, is optionally added to quench by protonation those carbanions to which no dye molecules attached.

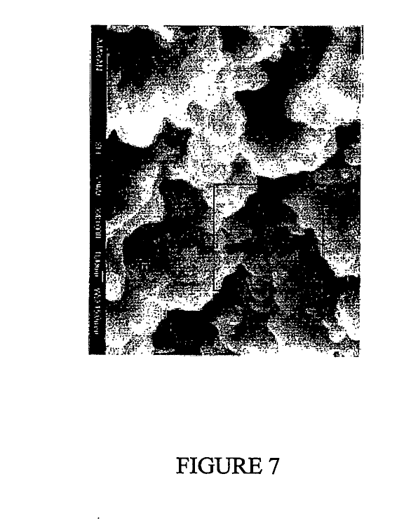

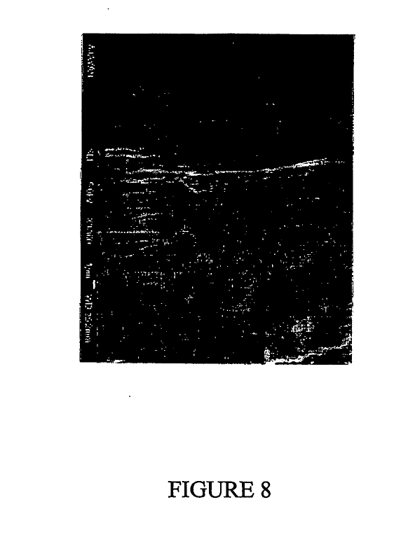

The organic dye molecules attached to the carbon nanotubes by the methods of the first or second preferred embodiments described above may be incorporated into a matrix, such as the polymer matrix by any suitable method. For example, the incorporation may be accomplished by either by mixing pre-formed polymers with the nanotube-dye structures in a common solvent or by dissolving the nanotube-dye structures in the monomer and subsequent polymerization. In the former method, for example, nanotubes are dissolved in toluene, along with a pre-formed polymer such as poly(methyl methacrylate). The dispersion is then precipitated using an antisolvent such as methanol to yield polymer nanotube composites. Alternatively, the nanotube-dye structures are dissolved in a monomer and subsequent polymerization, such as interfacial or suspension polymerization, is carried out to incorporate the nanotube-dye structures in the matrix. For example, for a nylon matrix, the process would be as follows. The nanotube-dye structures are dissolved in an organic phase containing dicarboxylic acid chloride, and diamine is dissolved in water. The two non-miscible liquid layers are superposed to yield a polyamide-nanotube composite at the interface, which is constantly pulled out (i.e., interfacial polymerization) to form a sheet or thread shaped matrix. For example, FIGS. 6 and 7 are SEM images of nanotubes embedded in a polymer matrix while FIG. 8 is an SEM image of nanotubes aligned along the polymer fiber stretching direction.

In general, the polymer matrix formation may optionally include solubilizing the nanotube structures with another organic material to form a suspended phase, and reacting with another organic component to produce a polymer surrounding the aligned nanotubes. The composite may then be formed in the morphological manner of a thin film, a thread, a web and/or a suspended but soluble or insoluble pellet for future morphological and device applications.

If desired, the aligned nanotubes can be optionally mixed with another organic solvent, that solvent using weak interactions such as van der Waals forces to maintain solubility, or mixed with an organic solvent containing a diacid or amine. The polymerization may follow pretreatment of one component of the polymerization step with carbon nanotubes. If desired, the alignment of the nanotubes within the polymer matrix may be used as a factor for morphological design and applications.

In general, organic molecules with specific absorptive tendencies, such as the organic dye molecules, are attached to the functionalized defect sites of the nanotubes. If it is desirable to align the nanotubes in the polymer matrix, then these treated molecules (SuperNanoMolecular (SNM) nano-structures) are then preferably embedded into a solution where interfacial polymerization occurs, and the nanotubes are aligned. The coatings that form the SuperNanoMolecular (SNM) structure are preferably covalently bound to the nanotubes. However, hydrophobic or electrostatic binding and even binding by van der Waals forces to keep the differing molecular structures in place may be used.

Furthermore, if desired, different types of photovoltaic organic molecules may be attached to the carbon nanotubes, wherein the different types of photovoltaic organic molecules have a peak sensitivity to different radiation wavelengths. This photovoltaic device, such as a solar cell or photodetector, is more sensitive to different radiation wavelength bands.

As noted above, the photovoltaic device preferably comprises a solar cell, but may also comprise a photodetector. In each device, a charge generating layer is located between two electrodes. In a solar cell, electricity is generated from solar radiation by exposing the solar cell to solar radiation, such that excitation transfer from the photovoltaic organic molecules to the carbon nanotubes results from the absorbed solar radiation. The photoelectric current (i.e., photocurrent) generated by the excitation transfer is collected at the electrodes contacting the solar cell. If the photovoltaic device is a photodetector, then the collected photoelectric current is used to determine the presence and/or the characteristics of the radiation (i.e., UV, visible or IR radiation) incident on the photodetector.

The solar cell photovoltaic device may have any suitable principle of operation. For example, the solar cell may comprise a Schottky type cell comprising a single charge generating layer (i.e., the polymer matrix material layer containing one type of organic photovoltaic molecule). In this case, one electrode material is selected to form a Schottky contact with the charge generating layer while the other electrode material is selected to form an ohmic contact with the charge generating layer. Charge separation occurs at the charge generating layer/Schottky contact interface. For example, the charge generating layer is drawn into a thin film where one side is contacted with an ohmic injector or electrode while the other is contacted with a Schottky contact or electrode. The Schottky contact can form a pn junction for enhanced carrier production under solar influences. In general, the organic solar cell layers contacts are selected to be p-type or n-type contacts depending on the doping (attachment tendencies) of the organic material.

In another example, the solar cell comprises a bilayer cell containing a heterojunction of two different charge generating organic layers, where the charge is generated at the heterojunction. One or both of the charge generating layers may comprise a matrix material layer each containing a different type of organic photovoltaic molecule. The operation of Schottky type and bilayer types of solar cells are described in U.S. Pat. No. 6,352,777, incorporated herein by reference in its entirety.

Any suitable organic photovoltaic material or materials may be used in the charge generating layer. For example, a cationic phenazine dye, such as PSF was described as the organic dye in the specific examples above. However, other suitable organic dyes usable in a solar cell, such as dyes selected from a group consisting of one or more of azo dyes, phthalocyanine dyes, quinine dyes, quinoline dyes, porphyryne dyes, pyrylium dyes and perylyne dyes may be attached to the nanotubes of the charge generating layer instead of or in combination with PSF. Preferably, the dyes comprise dye salts which are disassociated into cationic dyes for binding to the nanotube defect sites.

Examples of perylene dyes include 3,4,9,10-perylenetetracarboxylic dianhydride (PTCDA) and a 3,4,9,10-perylenetetracarboxylic-bis-benzimidazole (PTCBI). Examples of phthalocyanine dyes include copper phthalocyanine (CuPc) and zinc phthalocyanine (ZnPc). Examples of pyrylium dyes include pyrylium, thiapyrylium and selenapyrylium dye salts which may be disassocaited into cationic dyes. For example, a list of representative pyrylium dye salts is provided Table II of U.S. Pat. No. 4,125,414, incorporated herein by reference it its entirety.

The solar cell may have any number of other suitable layers in addition to the charge generating layer. For example, at least one of a p and n type charge transporting layers may be located adjacent the matrix material. If both p and n type charge transporting layers are present, then these layers are preferably located on opposite sides of the charge generating layer. The charge transporting layers may be arranged in any suitable configuration with respect to the charge generating layer(s) and the electrodes, as described in U.S. Pat. No. 6,352,777, incorporated herein by reference in its entirety. The charge transporting layers are preferably suitable organic material layers.

Examples of the organic charge transporting layer materials include hydrazone compounds, such as N-methyl-N-phenylhydrazino-3-methylidene-9-ethylcarbazole, and p-diethylaminobenzaldehyde-N-α-naphthyl-N-phenylhydrazone; benzidine compounds, such as 4-diethylamino-4′-diphenlaminobiphenyl; and styryl compounds, such as a-phenyl-4-N,N′-diphenylaminostilbene, and 5-(4-dimethylaminobenzylidene)-5H-dibenzo[and] cycloheptane, as described in U.S. Pat. No. 4,963,196, incorporated herein by reference in its entirety. Other photoconductors include the compounds listed in Table I, below, as provided in U.S. Pat. No. 4,125,414, incorporated herein by reference in its entirety.

TABLE I

| Compound | |
|---|---|
| No. | Name of Compound |
| 1 | 4,4′-benzylidenebis(N,N-diethyl-m-toluidine) |
| 2 | 4′,4″-diamino-4-dimethylamino-2′,2″-di- |
| | methyltriphenylmethane |
| 3 | 4′,4″-bis(diethylamino)-2,6-dichloro-2′,2″- |
| | dimethyltriphenylmethane |
| 4 | 4′,4″-bis(diethylamino)-2′,2″-dimethyldi- |
| | phenylnaphthylmethane |
| 5 | 2′,2″-dimethyl-4,4′4″-tris(dimethyl- |
| | amino)triphenylmethane |
| 6 | 4′,4″-bis(diethylamino)-4-dimethylamino-2′,2″- |
| | dimethyltriphenylmethane |
| 7 | 4′,4″-bis(diethylamino)-2-chloro-2′,2″-dimethyl-4- |
| | dimethylaminotriphenylmethane |
| 8 | 4′,4″-bis(diethylamino)-4-dimethylamino-2,2′,2″- |
| | trimethyltriphenylmethane |
| 9 | 4′,4″-bis(dimethylamino)-2-chloro-2′,2″- |
| | dimethyltriphenylmethane |
| 10 | 4′,4″-bis(dimethylamino)-2′,2″-dimethyl-4- |
| | methoxytriphenylmethane |
| 11 | bis(4-diethylamino)-1,1,1-triphenylethane |
| 12 | bis(4-diethylamino)tetraphenylmethane |
| 13 | 4′,4″-bis(benzylethylamino)-2′,2″- |
| | dimethyltriphenylmethane |
| 14 | 4′,4″-bis(diethylamino)-2′,2″- |
| | diethoxytriphenylmethane |
| 15 | 4,4′-bis(dimethylamino)-1,1,1-triphenylethane |
| 16 | 1-(4-N,N-dimethylaminophenyl)-1,1-diphenylethane |
| 17 | 4-dimethylaminotetraphenylmethane |
| 18 | 4-diethylaminotetraphenylmethane |
| 19 | 4-di-p-tolylamino-4′-[4-(di-p- |
| | tolylamino)styryl]stilbene |
| 20 | 4-di-p-diethylaminophenylamino-4′-[4-di-(p- |
| | diethylaminophenylamino)styryl]-stilbene |
| 21 | tri-p-tolylamine |
| 22 | 1,1-bis(4-di-p-tolylaminophenyl)cyclohexane |

The photovoltaic device further comprises two electrodes. If the photovoltaic device is a sheet shaped solar cell, then at least one electrode is preferably transparent to radiation, such as an indium tin oxide, indium oxide, zinc oxide or zinc indium tin oxide electrode. Other suitable electrode materials include nickel, gold, silver, magnesium, indium, aluminum and alloys thereof as well as conductive organic electrode layers, such as conductive polymer polyanaline (PANI). For example, for a Schottky type solar cell, a high work function metal such as Au may be used as a Schottky contact for n-type photoconductors while low work function metals such as Al, Mg or In may be used as a Schottky contact for p-type photoconductors. For a bilayer cell, a high work function metal such as Au may be used as an ohmic positive or anode electrode while low work function metals such as Al, Mg, or In may be used as an ohmic negative or cathode electrode. The electrodes may contact the charge generating and/or the charge transporting layer(s) if present.

For example, as described in U.S. Pat. No. 6,352,777, exemplary bilayer solar cells may have the following organic and electrode layer configurations: ITO/CuPc/PTDCA/In and ITO/CuPc/PTCBI/Ag. Other suitable bilayer solar cell organic and electrode layer configurations are described in Table I of U.S. Pat. No. 6,352,777. It should be noted that the solar cell structures of the embodiments of the present invention differ from those of U.S. Pat. No. 6,352,777 in that the dye in the charge generating layer is bound to nanotubes, while the dyes in U.S. Pat. No. 6,352,777 are not bound to nanotubes.

Any suitable polymer matrix material may be used. Polymer matrices that are contemplated by an embodiment of the invention include, without limitation, a polyamide, polyester, polyurethane, polysulfonamide, polycarbonate, polyurea, polyphosphonoamide, polyarylate, polyimide, poly(amic ester), poly(ester amide), a poly(enaryloxynitrile) matrix or mixtures thereof.

In another embodiment, the matrix is a poly(ester amide)s related to nylons and polyesters 6,10 or 12,10. For example, poly(ester amide)s may comprises copolymers, such as poly(butylene adipate)-co-(amino caproate).

In still another embodiment, the matrix is selected from the following polymers or mixed polymers: polycarbonate/polybutylene terphthalate (PC/PBT), polycarbonate/polyethylene terephthalate (PC/PET), polyamide (PA) reinforced with modified polyphenylene ether (PPE), polyphenylene suphide (PPS), polybutylene terephthalate (PBT), polyethylene terephthalate (PET), polyetherimide, expandable polystyrene poly(2,6-dimethyl-1,4-phenylene ether (PPE), modified polyphenylene ether (PPE), polycarbonate (PC), acrylic-styrene-acrylonitrile (ASA), polycarbonate/acrylonitrile-butadiene-styrene (PC/AILS) and acrylonitrile-butadiene-styrene (ABS), or mixtures thereof.

Preferably, the solar cell comprises a flexible sheet type solar cell. In this case, the matrix material comprises a flexible thin film or a flexible thread that is formed on a substrate, and an overall stiffness of the solar cell is determined by a stiffness of the substrate. Thus, by selecting an appropriate substrate or supporting surface, the stiffness of the photovoltaic device may be selected. The flexible, highly efficient solar cells described above can be used on any surface or substrate. This would allow them to be applied to any surface, such as a curved, stepped or otherwise irregular surface that receives sufficient light for energy production without the cost of expensive mounts and cabling.

The solar cell containing the matrix material may be formed on an outer surface of a space suit or a space ship. For example, the flexible solar panels of the solar cells comprise a surface layer of flexible material for use in space suits. This would allow astronauts to work in environments without so much cumbersome equipment to carry that is used to produce energy for the suits. In addition, the astronaut becomes more self-sufficient and less dependent on the supplies brought up in the space vehicle. For the spacecraft itself, this power generation will lower the overall weight needed to propel the craft into space. While the weight reduction is comparatively low for space suits, it is a substantial reduction when considering solar panels used in solar sails for satellites. Given that organic materials can be more efficient that inorganics when generating photocarriers, the efficiencies of the organic solar cells described herein may be higher than those of conventional solar cells.

From the foregoing description, one skilled in the art can easily ascertain the essential characteristics of this invention, and without departing from the spirit and scope thereof, can make various changes and modifications of the invention to adapt it to various usages and conditions without undue experimentation. All patents, patent applications and publications cited herein are incorporated by reference in their entirety.

1. An organic photovoltaic conversion device comprising:
a matrix material;
carbon nanotubes dispersed in the matrix material; and
photovoltaic organic molecules attached to defect sites on the carbon nanotubes.

2. The device of claim 1, wherein the photovoltaic organic molecules are adapted to generate a photocurrent upon absorbing radiation.

3. The device of claim 1, wherein the photovoltaic organic molecules are chemisorbed to the defect sites on the carbon nanotubes such that the absorbed radiation provides excitation transfer from the photovoltaic organic molecules to the carbon nanotubes.

4. The device of claim 1, wherein the photovoltaic organic molecules comprise organic dye molecules.

5. The device of claim 1, wherein the device comprises a solar cell.

6. The device of claim 1, wherein the device comprises a photodetector.

7. The device of claim 1, wherein the defect sites on the carbon nanotubes comprise a carboxyl group or a C1-6 alkyl group.

8. The device of claim 7, wherein the C1-6 alkyl group comprises a sec-butyl group.

9. The device of claim 1, wherein:
the matrix material comprises a polymer matrix material; and
the carbon nanotubes are well dispersed in the polymer matrix material.

10. The device of claim 9, wherein the polymer matrix material is selected from a group consisting of polyamide, polyester, polyurethane, polysulfonamide, polycarbonate, polyurea, polyphosphonoamide, polyarylate, polyimide, poly(amic ester), poly(ester amide), a poly(enaryloxynitrile) matrix or mixtures thereof.

11. The device of claim 4, wherein the organic dye comprises a phenazine dye.

12. The device of claim 11, wherein the dye comprises PSF.

13. The device of claim 5, wherein the organic dye is selected from a group consisting of one or more of azo dyes, phthalocyanine dyes, quinine dyes, quinoline dyes, porphyryne dyes, pyrylium dyes and perylyne dyes.

14. The device of claim 5, further comprising at least one of a p and n type charge transporting layers located in contact with the matrix material.

15. The device of claim 14, wherein the charge transporting layers are selected from a group consisting of hydrazone compounds, benzidine compounds and styryl compounds.

16. The device of claim 1 further comprising different types of photovoltaic organic molecules attached to the carbon nanotubes, wherein the different types of molecules have a peak sensitivity to different radiation wavelengths.

17. The device of claim 5, further comprising two electrodes.

18. The device of claim 16, wherein at least one electrode is transparent to radiation.

19. The device of claim 5, wherein the solar cell comprises a Schottky type cell comprising a single charge generating layer comprising the matrix material layer containing one type of organic photovoltaic molecule.

20. The device of claim 5, wherein the solar cell comprises a bilayer cell containing a heterojunction of two charge generating layers each containing a different type of organic photovoltaic molecule.

21. The device of claim 1, wherein:
the matrix material comprises a flexible thin film or a flexible threat that is formed on a substrate; and
an overall stiffness of the device is determined by a stiffness of the substrate.

22. The device of claim 1, wherein the carbon nanotubes are aligned in a controlled manner in the matrix material.

23. The device of claim 1, wherein the matrix material is formed on an outer surface of a space suit or a space ship.

24. A method of making an organic photovoltaic conversion device comprising:
forming defect sites on carbon nanotubes;
attaching photovoltaic organic molecules to the defect sites on the carbon nanotubes; and
incorporating the nanotubes and the photovoltaic organic molecules into a matrix material.

25. The method of claim 24, wherein:
the photovoltaic organic molecules are adapted to generate a photocurrent upon absorbing radiation;
the photovoltaic organic molecules are chemisorbed to the defect sites on the carbon nanotubes such that the absorbed radiation allows excitation transfer from the photovoltaic organic molecules to the carbon nanotubes; and
the photovoltaic organic molecules comprise organic dye molecules.

26. The method of claim 24, wherein:
the step of forming defect sites comprises reacting the carbon nanotubes with an anionic initiatior thereby generating anions on the surface of the carbon nanotubes;
the step of attaching photovoltaic organic molecules comprises covalently bonding the photovoltaic organic molecules to the anions.

27. The method of claim 26, wherein the anionic initiator comprises an alkyllithium salt.

28. The method of claim 27, wherein the alkyllithium salt is sec-butyllithium which forms sec-butyl groups on the carbon nanotubes.

29. The method of claim 24, wherein:
the step of forming defect sites comprises reacting the carbon nanotubes with an acid thereby generating carboxyl groups on the surface of the carbon nanotubes;
the step of attaching photovoltaic organic molecules comprises covalently bonding the photovoltaic organic molecules to the carboxyl groups.

30. The method of claim 29, wherein the acid comprises a mixture of sulfuric and nitric acids.

31. The method of claim 24, wherein the step of incorporating the nanotubes and the photovoltaic organic molecules into a matrix material comprises incorporating the nanotubes and the photovoltaic organic molecules into a polymer matrix material.

32. The method of claim 31, wherein the polymer matrix material comprises a flexible polymer thin film or a flexible polymer thread.

33. The method of claim 32, wherein the step of incorporating the nanotubes and the photovoltaic organic molecules into the polymer matrix material comprises incorporating carbon nanotubes and the attached photovoltaic organic molecules into the polymer matrix material by interfacial polymerization.

34. The method of any of claim 24, wherein the device comprises a solar cell.

35. The method of any of claim 24, wherein the device comprises a photodetector.

36. The method of claim 31, wherein the polymer matrix material is selected from a group consisting of polyamide, polyester, polyurethane, polysulfonamide, polycarbonate, polyurea, polyphosphonoamide, polyarylate, polyimide, poly(amic ester), poly(ester amide), a poly(enaryloxynitrile) matrix or mixtures thereof.

37. The method of claim 25, wherein the organic dye comprises a phenazine dye.

38. The method of claim 25, wherein the organic dye is selected from a group consisting of one or more of azo dyes, phthalocyanine dyes, quinine dyes, quinoline dyes, porphyryne dyes, pyrylium dyes and perylyne dyes.

39. The method of claim 34, further comprising forming at least one of a p and n type charge transporting layers in contact with the matrix material.

40. The method of claim 34, further comprising forming two electrodes in contact with organic layers of the solar cell.

41. A method of generating electricity from solar radiation comprising exposing the solar cell of claim 5 to solar radiation such that excitation transfer from the photovoltaic organic molecules to the carbon nanotubes results from the absorbed solar radiation.

42. The method of claim 41, further comprising collecting a photoelectric current generated by the excitation transfer at electrodes contacting the solar cell.
